(19) United States
(12) Patent Application Publication
(10) Pub. No.: US 2006/0077412 A1
(43) Pub. Date: Apr. 13, 2006

(54) Method and apparatus for optimizing data transmission costs

(76) Inventors: Vikram Phogat, Bangalore (IN); Haripriya Surampudi, Bangalore (IN)

Correspondence Address: DILLON & YUDELL LLP, 8911 NORTH CAPITAL OF TEXAS HWY, SUITE 2110, AUSTIN, TX, 78759, US

(21) Appl. No.: 10/963,069

(22) Filed: Oct. 11, 2004

(51) Int. Cl. G06F 3/12

(52) U.S. Cl. 358/1.13

(57) ABSTRACT

A method for optimizing data transmission costs is disclosed. A compressibility test is performed on a number of bits within an observation interval during a data transmission. Once the length of the observation interval for a data transmission mode has been selected, the value of savings achieved during the data transmission can be determined. The value of savings is then compared to a predetermined threshold saving value set for either a compressed mode or an uncompressed mode. If the value of the savings achieved in a compressed mode is less than the predetermined threshold saving value set for the compressed mode, then the data transmission mode is switched from the compressed mode to an uncompressed mode. On the other hand, if the value of savings achieved in the uncompressed mode is greater than the predetermined threshold saving value set for the uncompressed mode, then the data transmission mode is switched from the uncompressed mode to the compressed mode.

### BACKGROUND OF THE INVENTION

1. Technical Field

The present invention relates to data transmissions in general, and in particular to a method and apparatus for optimizing the costs of data transmissions.

2. Description of Related Art

Under the ITU-T V.44 compression standard, compressed data include ordinals, codewords and string extensions. An ordinal is basically the transmission of a character in its true form. A codeword specifies the node representing a substring. A string extension specifies the length of a new substring generated after the previous codeword has been transmitted. The bits required to transmit ordinals, codewords and string extensions are summarized in Table I.

When transmitting correlated data, the usage of a dictionary based data compression scheme offers a significant advantage in transmission cost over the true (i.e., uncompressed) form of the same data. However, when transmitting uncorrelated data, the cost of transmitting data in their compressed form can sometimes be greater than the cost of transmitting the same data in their true form. This is because, in most data transmission systems, only one byte (8 bits) is typically required for transmitting a character in its true form. In contrast, a variable number of bits is needed for transmitting a codeword in a compressed mode, depending on the number of codewords generated (as shown in Table I).

TABLE I

| compressed | minimum length | maximum length | comments |
|---|---|---|---|
| data | (bits) | (bits) | (bits) |
| ordinal | 8 | 10 | 1-2 bits are used to indicate that a |
| | | | transmitted code being an ordinal. The |
| | | | actual ordinal is represented in 7 bits, |
| | | | until an ordinal greater than 127 is |
| | | | transmitted. The ordinal size for all |
| | | | ordinals thereafter is 8 bits. |
| codeword | 7 | log₂ N + 1 | 1 bit is used to indicate that a |
| | | where N is the | transmitted code being a codeword. |
| | | maximum number of | The number of bits used to transmit the |
| | | codewords possible | codeword is determined by log₂ C, |
| | | | where C is the number of codewords |
| | | | generated. For a dictionary of |
| | | | maximum size of 1,024 codewords, the |
| | | | codeword size can extend to 11 bits. |
| string | 3 | 9 | 2 bits are used to indicate that the |
| extension | | | transmitted code being a string |
| | | | extension. The string extension can |
| | | | take from 1 to 7 bits, depending on the |
| | | | string extension being transmitted. |

For uncorrelated data, such as binary data streams, the repetition of string patterns is minimal. Thus, when uncorrelated data is compressed, the compressed output mainly includes ordinals and codewords representing strings of two or less number of characters. Because the number of codewords generated is more than those of compressible data, the number of bits required to transmit a codeword is also higher. As such, the number of bytes required to transmit compressed uncorrelated data can be significantly greater than the number of bytes required to transmit uncorrelated data in their true form.

### SUMMARY OF THE INVENTION

In accordance with a preferred embodiment of the present invention, a compressibility test is performed on a number of bits within an observation interval during a data transmission. Once the length of the observation interval for a data transmission mode has been selected, the value of savings achieved during the data transmission can be determined. The value of savings is then compared to a predetermined threshold saving value set for either a compressed mode or an uncompressed mode. If the value of the savings achieved in a compressed mode is less than the predetermined threshold saving value set for the compressed mode, then the data transmission mode is switched from the compressed mode to an uncompressed mode. On the other hand, if the value of savings achieved in the uncompressed mode is greater than the predetermined threshold saving value set for the uncompressed mode, then the data transmission mode is switched from the uncompressed mode to the compressed mode.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a high-level logic flow diagram of a method for optimizing the cost of data transmissions, in accordance with a preferred embodiment of the present invention; and

FIG. 2 is a block diagram of a data compression system in which a preferred embodiment of the present invention is incorporated.

### DETAILED DESCRIPTION OF A PREFERRED EMBODIMENT

The present invention provides a method to achieve an optimum cost for data transmissions by switching between a compressed mode and an uncompressed (or transparent) mode based on a compressibility test. The compressibility test is carried out for every N bits of output data that may be compressed or uncompressed, wherein N is a number of bits within an observation interval selected for performing the compressibility test. In each observation interval, the length of an input bit stream provided to a data compressor (or encoder) that results in N bits of output, and the length of a compressed output bit stream for the same input bit stream are recorded.

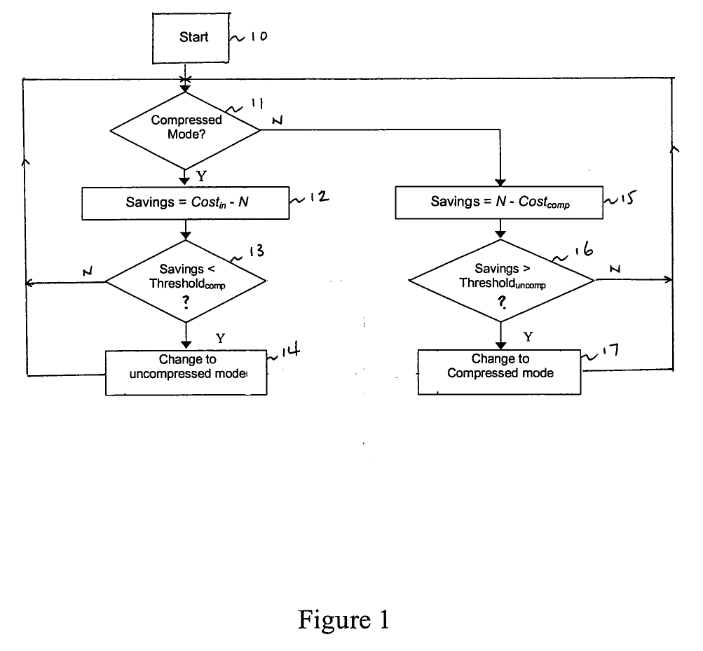

Referring now to the drawings and in particular to FIG. 1, there is depicted a high-level logic flow diagram of a method for optimizing the cost of data transmissions, in accordance with a preferred embodiment of the present invention. Starting in block 10, a determination is made as to whether or not data are being transmitted in a compressed mode, as shown in block 11.

If the data are being transmitted in the compressed mode, the value of savings achieved when data are being transmitted in the compressed mode is determined, as depicted in block 12. Specifically, the value of savings achieved when data are being transmitted in the compressed mode can be estimated by determining the difference between the length of an input bit stream provided to a data compressor that results in a predetermined number of bits N at the output (Costᵢₙ) and the predetermined number of bits N within an observation interval for data transmissions in the compressed mode, as follows:
Savings_{comp}=Costᵢₙ−N
The predetermined number of bits N within an observation interval for data transmissions in the compressed mode is preferably calculated by:
N=K_{comp}*CTI
where K_{c} is a design parameter that can be used to set the relative observation interval for the compressed mode, and CTI is the compressibility test interval.

A determination is then made as to whether or not the savings achieved when the data compressor is working in the compressed mode falls below a predetermined threshold saving value set for the compressed mode (Threshold_{comp}), as shown in block 13. If the savings achieved when the data compressor is working in the compressed mode fall below the predetermined threshold saving value set for the compressed mode, then the data transmission mode is switched from the compressed mode to the uncompressed mode, as depicted in block 14. Otherwise, if the savings achieved when the data compressor is working in the compressed mode do not fall below the predetermined threshold saving value set for the compressed mode, then the data transmission mode remains to be in the compressed mode.

However, if the data are being transmitted in an uncompressed mode, the value of savings achieved when data are being transmitted in the uncompressed mode is determined, as shown in block 15. Specifically, the value of savings achieved when data are being transmitted in the uncompressed mode is estimated by determining the difference between a predetermined number of bits N within an observation interval for data transmissions in the uncompressed mode and the length of the compressed output bit stream for the same input bit stream (Cost_{comp}), as follows:
Savings=N−Cost_{comp}
The predetermined number of bits N within an observation interval for data transmissions in the uncompressed mode is preferably calculated by
N=Kₜ*CTI
where Kₜ is a design parameter that can be used to set the relative observation interval for the uncompressed mode, and CTI is the compressibility test interval. The observation interval for the uncompressed mode is generally set to be larger than the observation interval of the compressed mode in order to obtain reliable detection of data compressibility.

A determination is then made as to whether or not the savings achieved when the data compressor is working in the uncompressed mode is greater than a predetermined threshold saving value set for the uncompressed mode (Threshold_{uncomp}), as depicted in block 16. If the savings achieved when the data compressor is working in the uncompressed mode is greater than the predetermined threshold saving value set for the uncompressed mode, then the data transmission mode is switched from the uncompressed mode to the compressed mode, as shown in block 17. Otherwise, if the savings achieved when the data compressor is working in the uncompressed mode is less than the predetermined threshold saving value set for the uncompressed mode, then the data transmission mode remains to be in the uncompressed mode.

Every mode change is associated with a cost. Whenever the data compressor performs a transmission mode switching, the data compressor has to terminate the current transmission mode in a defined manner and then transmits some control codes. Such cost determines the thresholds for the above-mentioned compressibility test. The cost of uncompressed-to-compressed mode switching is different from the cost of compressed-to-uncompressed mode switching. Also, the cost for each compressed-to-uncompressed mode switching can be different and should be calculated in real time.

As an alternative embodiment, a constant threshold, which is an average of all costs possible, can be used for all cost estimations. The value of compressibility test interval (or CTI) depends on the history and dictionary size used for compression. The larger the history and dictionary size, the larger the value of CTI should be. An exemplary set of values of interval and thresholds is listed in Table II.

TABLE II

| | |
|---|---|
| CTI | 1536 |
| K_{c} | 1 |
| Kₜ | 4 |
| Threshold_{comp} | 30 |
| Threshold_{uncomp} | 16 |

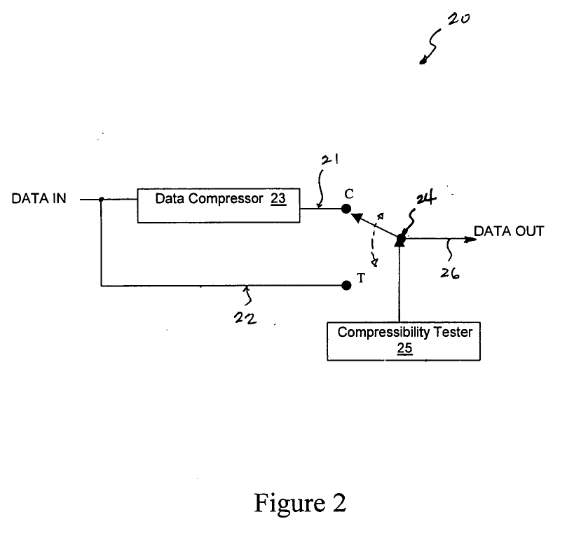

With reference now to FIG. 2, there is depicted a block diagram of a data compression system in which a preferred embodiment of the present invention is incorporated. As shown, a data compression system 20 includes a transmission path 21 and a transmission path 22. Transmission path 21 is for transmitting compressed data, and transmission path 22 is for transmitting uncompressed data (where bit stuffing is performed). A data compressor (or encoder) 23 is provided within transmission path 21 for compressing data.

A switch 24 can be selectively connected to either transmission path 21 at a node C or transmission path 22 at a node T. A compressibility tester 25, which determines whether data transmission should be in a compressed mode or an uncompressed mode, is utilized to control the connection position of switch 24. Compressibility tester 25 preferably performs the method of the present invention as explained in FIG. 1 to determine whether data transmissions should be performed in the compressed mode or uncompressed mode. Compressibility tester 25 includes an estimator (not shown) for estimating the value of savings achieved during data transmission in the compressed mode and uncompressed mode. Compressibility tester 25 also includes a comparator (not shown) for comparing the savings achieved with a predetermined threshold saving values set for the compressed mode and uncompressed mode. Depending on the connection position of switch 24, data at an output 26 can be either in the compressed form or in the uncompressed form.

As has been described, the present invention provides a method and apparatus for optimizing data transmission costs.

It is also important to note that although the present invention has been described from a hardware perspective, those skilled in the art will appreciate that the mechanisms of the present invention are capable of being distributed as a program product in a variety of forms, and that the present invention applies equally regardless of the particular type of signal bearing media utilized to actually carry out the distribution. Examples of signal bearing media include, without limitation, recordable type media such as floppy disks or hard drives, and transmission type media such as analog or digital communications links.

While the invention has been particularly shown and described with reference to a preferred embodiment, it will be understood by those skilled in the art that various changes in form and detail may be made therein without departing from the spirit and scope of the invention.

What is claimed is:

1. A method for optimizing data transmission costs, said method comprising:
in response to data being transmitted in a compressed mode,
estimating value of savings achieved in said compressed mode; and
switching data transmissions from said compressed mode to an uncompressed mode when said estimated value of savings achieved in said compressed mode is lesser than a predetermined threshold saving value set for compressed data transmissions; and
in response to data being transmitted in said uncompressed mode,
estimating value of savings achieved in said uncompressed mode; and
switching from said uncompressed mode to said compressed mode when said estimated value of savings achieved in said uncompressed mode is greater than a predetermined threshold saving value set for uncompressed data transmissions.

2. The method of claim 1, wherein said method further includes selecting an observation interval having a predetermined number of bits for said compressed mode.

3. The method of claim 2, wherein a number of bits in said observation interval for said compressed mode is determined by taking a product of a predetermined compressibility test interval and a design parameter set for compressed data transmissions.

4. The method of claim 2, wherein said value of savings achieved in said compressed mode is estimated by determining a difference between the length of an input bit stream provided to a data compressor that results in a predetermined number of bits as output in said observation interval set for said compressed mode and a predetermined number of bits in said observation interval.

5. The method of claim 1, wherein said method further includes selecting an observation interval having a predetermined number of bits for said uncompressed mode.

6. The method of claim 5, wherein a number of bits in said observation interval for said uncompressed mode is determined by taking a product of a predetermined compressibility test interval and a design parameter set for uncompressed data transmissions.

7. The method of claim 5, wherein said value of savings achieved in said uncompressed mode is estimated by determining a difference between said predetermined number of bits in said observation interval set for said uncompressed mode and the length of said compressed output bit stream from said data compressor for said input bit stream.

8. A computer program product residing on a computer usable medium for optimizing data transmission costs, said computer program product comprising:
in response to data being transmitted in a compressed mode,
program code means for estimating value of savings achieved in said compressed mode; and
program code means for switching data transmissions from said compressed mode to an uncompressed mode when said estimated value of savings achieved in said compressed mode is lesser than a predetermined threshold saving value set for compressed data transmissions; and
in response to data being transmitted in said uncompressed mode,
program code means for estimating value of savings achieved in said uncompressed mode; and
program code means for switching from said uncompressed mode to said compressed mode when said estimated value of savings achieved in said uncompressed mode is greater than a predetermined threshold saving value set for uncompressed data transmissions.

9. The computer program product of claim 8, wherein said computer program product further includes program code means for selecting observation intervals having a predetermined number of bits for said compressed mode.

10. The computer program product of claim 9, wherein a number of bits in said observation interval for said compressed mode is determined by taking a product of a predetermined compressibility test interval and a design parameter set for compressed data transmission.

11. The computer program product of claim 9, wherein said value of savings achieved in said compressed mode is estimated by determining a difference between a length of said input bit stream provided to a data compressor that results in a predetermined number of bits as output in said observation interval set for said compressed mode and a predetermined number of bits within said observation interval.

12. The computer program product of claim 8, wherein said computer program product further includes program code means for selecting observation intervals having a predetermined number of bits for said uncompressed mode.

13. The computer program product of claim 12, wherein a number of bits in said observation interval for said uncompressed mode is determined by taking a product of a predetermined compressibility test interval and a design parameter set for uncompressed data transmission.

14. The computer program product of claim 12, wherein said value of savings achieved in said uncompressed mode is estimated by determining a difference between said predetermined number of bits within said observation interval set for said uncompressed mode and a length of said compressed output bit stream from said data compressor for said input bit stream.

15. An apparatus for optimizing data transmission costs, said apparatus comprising:
a compressed data transmission path and an uncompressed data transmission path, wherein said compressed data transmission path includes a data compressor;
a switching means configured to be selectively connected to either said compressed data transmission path or said uncompressed data transmission path; and
a compressibility testing means for estimating a value of savings achieved in a compressed mode and an uncompressed mode and for comparing said value of savings achieved with predetermined threshold saving values set for said compressed mode and said uncompressed mode.

16. The apparatus of claim 15, wherein said value of savings achieved in said compressed mode is estimated by determining a difference between a length of said input bit stream provided to said data compressor that results in a predetermined number of bits as output in an observation interval set for said compressed mode and a predetermined number of bits within said observation interval.

17. The apparatus of claim 15, wherein said value of savings achieved in said uncompressed mode is estimated by determining a difference between said predetermined number of bits within said observation interval set for said uncompressed mode and a length of said compressed output bit stream from said data compressor for said input bit stream.
